(19) United States
(12) Patent Application Publication
(10) Pub. No.: US 2025/0098549 A1
(43) Pub. Date: Mar. 20, 2025

(54) Fabrication of Through-Silicon Vias

(71) Applicant: IMEC VZW, Leuven (BE)

(72) Inventors: Robert Miller, Lubbeek (BE); Jaber Derakhshandeh, Tienen (BE); Anna Herr, Ellicot City, MD (US)

(21) Appl. No.: 18/468,181

(22) Filed: Sep. 15, 2023

(51) Int. Cl. H10N 60/80; H01L 23/48; H01L 25/065; H10N 60/01

(52) U.S. Cl. CPC H10N 60/80; H01L 23/481; H01L 25/0657; H10N 60/01; H01L 2225/06513; H01L 2225/06541

(57) ABSTRACT

A through-silicon via (TSV) and methods for its manufacture are disclosed. An example TSV includes a core that extends through a substrate along an axis. The core includes a conductive material. The TSV also includes an outer layer that is disposed about the axis. The outer layer is at least partially surrounding the core. The outer layer includes a superconductive material. The TSV additionally includes an insulating layer that electrically insulates the core and the outer layer from one another.

### FIELD OF THE DISCLOSURE

The present description relates to the field of superconducting through-silicon vias (TSV). More specifically it relates to a fabrication process for forming a TSV having a core of conducting material and an outer layer of superconducting material, the conductive layers being separated by an oxide layer.

### BACKGROUND

Cryogenic technologies are currently considered as a potential solution for large computation applications with high energy efficiency. Due to their operating temperature, cryogenic systems can provide extreme packaging density on a substrate and between multiple substrates. Three-dimensional integration of cryogenically-compatible circuitry is viewed as one of the critical enablers for scaling these systems.

However, there exist no well-developed packaging processes that include superconducting and standard conductive metallization for 3D integrated circuits having silicon interposers.

Accordingly, there is a need for improved superconducting TSV devices and corresponding fabrication methods in order to provide superconductive and thermally conductive via paths, accommodate higher current density and lower losses, and provide dual operating temperature capability.

### SUMMARY

The present embodiments relate to a superconducting through-silicon via (TSV) and method for its fabrication. Various methods describe the fabrication process of a superconducting TSV having a core that is made of a conducting material while the outer layer is made of superconducting material. The method includes forming two electrically conductive channels that are separated by an insulating layer. The present disclosure also describes the resulting component created through such a fabrication process. The TSVs and methods for their manufacture described herein may beneficially enable three-dimensional integration of superconducting circuits with a higher circuit density than conventional means. In various embodiments, a hybrid Cu/NbTiN metallization on a silicon interposer may enable devices with thermally-decoupled heterogeneous systems having dual operating temperatures. As just one example, the TSV and methods described herein may beneficially remove communication bottlenecks and/or computational limitations. In such scenarios, the presently disclosed examples may enable superconducting digital (SCD) artificial intelligence (AI) and other high-performance computing (HPC) systems.

SCD, in particular, is a computer hardware technology aiming to provide sustainable growth for executing large advanced AI models. SCD offers computation at greatly reduced cost, form factor, and power consumption due to improved power efficiency, computational density, and interconnect bandwidth. SCD applications can drive the development of packaging with 300 GHz of analog bandwidth per wire between dies and boards, wires with negligible dissipation and dispersion up to 100's GHz frequencies, active devices with ps time scale and sub-attoJoule energy scale, and quantum accurate encoding of digital information. The fundamental energy dissipation per switching event in SCD does not depend on fabrication node, as with CMOS, but instead is set relative to thermal noise. As such, SCD is the only digital technology operating at thermodynamic limits while supporting a high clock rate of 10's GHz at a relaxed 30 nm lithography node.

Superconducting architectures offer 20× higher clock rates at 100× less power on-chip, and 10,000× more energy efficient interconnects chip-to-chip at the on-chip clock rate compared to traditional circuits. Cryogenic cooling is applied volumetrically to the entire system as opposed to individual dies, resulting in extremely high packaging density with all components of the ExaFlop-scale system being physically and electrically close. The technology supports heterogeneous architectures and enables dense packaging with stacking of dies for both memory and compute. High computational density and interconnect removes communication bottlenecks between AI cores that are physically distributed across multiple chips and boards. Simultaneous access to DRAM across all boards is a key differentiator. With interconnects becoming more and more like the human brain, such an architecture enables transparent data movement, faster training, and smarter models.

In addition, SCD disrupts the AI market by redefining ExaScale servers capable of datacenter performance, enabling low-latency real-time-data applications by removing computational bottlenecks behind reinforcement learning, multi-task learning, and data processing close to the edge. Enabling these workloads will fuel AI market growth in areas such as 6G fog computing, robotics, self-driving cars, healthcare, national power grids, logistics (planes, trains, and shipping), meta-learning, and more.

SCD is situated along-side CMOS and represents a practical step towards quantum computing. Superconducting qubits are among the most promising implementations of quantum computing, with investment growing above $1B in 2022. A quantum AI processor at scale will require a classical “supercomputer” backend compatible in energy scale, materials, and fabrication processes. The merging of superconductor quantum and classical digital hardware is a promising approach with the maturing of quantum computing within a decade.

In a first aspect, a through-silicon via (TSV) is provided. The TSV includes a core that extends through a substrate along an axis. The core includes a conductive material. The TSV also includes an outer layer. The outer layer is disposed about the axis and is at least partially surrounding the core. The outer layer includes a superconductive material. The TSV further includes an insulating layer that electrically insulates the core and the outer layer from one another.

In a second aspect, a method for forming a through-silicon via (TSV) is provided. The method includes etching a cavity in a substrate. The method also includes forming a first insulating layer along a sidewall of the cavity. The method additionally includes forming an outer layer on the first insulating layer within the cavity. The outer layer includes a superconductive material. The method yet further includes forming a second insulating layer on the outer layer within the cavity and forming a seed material on the second insulating layer within the cavity. The method includes forming a core on the seed material within the cavity, wherein the core comprises a conductive material.

Particular aspects of the embodiments are set out in the accompanying independent and dependent claims. Features from the dependent claims may be combined with features of the independent claims and with features of other dependent claims as appropriate and not merely as explicitly set out in the claims.

These and other aspects will be apparent from and elucidated with reference to the embodiment(s) described hereinafter.

### BRIEF DESCRIPTION OF THE FIGURES

The above, as well as additional, features will be better understood through the following illustrative and non-limiting detailed description of example embodiments, with reference to the appended drawings.

FIG. 1 illustrates a block diagram of a Through-Silicon Via (TSV) in accordance with example embodiments.

FIG. 2A illustrates a cross-sectional side view of a TSV and associated stackup in accordance with an example embodiments.

FIG. 2B illustrates a cross-sectional side view of a TSV in accordance with an example embodiments.

FIG. 2C illustrates a cross-sectional top-down view of a TSV in accordance with

an example embodiments.

FIG. 2D illustrates a cross-sectional top-down view of a split-channel TSV in accordance with an example embodiments.

FIG. 3 illustrates various blocks of a method of manufacturing a TSV in accordance with an example embodiments.

FIG. 4 illustrates a method for forming a through-silicon via (TSV) in accordance with an example embodiments.

FIG. 5A illustrates a cross-sectional side view and a top-down view of a TSV in accordance with an example embodiments.

FIG. 5B illustrates a cross-sectional side view and a top-down view of a TSV in accordance with an example embodiments.

FIG. 5C illustrates a cross-sectional side view and a top-down view of a TSV in accordance with an example embodiments.

FIG. 5D illustrates a cross-sectional side view and a top-down view of a TSV in accordance with an example embodiments.

FIG. 5E illustrates a cross-sectional side view and a top-down view of a TSV in accordance with an example embodiments.

Any reference signs in the claims shall not be construed as limiting the scope.

In the different drawings, the same reference signs refer to the same or analogous elements.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The drawings described are only schematic and are non-limiting. In the drawings, the size of some of the elements may be exaggerated and not drawn on scale for illustrative purposes. The dimensions and the relative dimensions do not correspond to actual reductions to practice of the embodiments.

Moreover, the terms top, under and the like in the description and the claims are used for descriptive purposes and not necessarily for describing relative positions. It is to be understood that the terms so used are interchangeable under appropriate circumstances and that the embodiments described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present embodiments, the only relevant components of the device are A and B.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments, various features are sometimes grouped together in a single embodiment, figure, or description thereof for the purpose of streamlining the disclosure and aiding in the understanding of one or more of the various aspects. This method of disclosure, however, is not to be interpreted as reflecting an intention that the claimed embodiments requires more features than are expressly recited in each claim. Rather, as the following claims reflect, aspects lie in less than all features of a single foregoing disclosed embodiment. Thus, the claims following the detailed description are hereby expressly incorporated into this detailed description, with each claim standing on its own as a separate embodiment.

Furthermore, while some embodiments described herein include some but not other features included in other embodiments, combinations of features of different embodiments are meant to be within the scope, and form different embodiments, as would be understood by those in the art. For example, in the following claims, any of the claimed embodiments can be used in any combination.

In the description provided herein, numerous specific details are set forth. However, it is understood that embodiments may be practiced without these specific details. In other instances, well-known methods, structures and techniques have not been shown in detail in order not to obscure an understanding of this description.

### Example Through-Silicon Vias

To fully exploit the full potential of cryogenic technologies, 3D integrated circuits components need to be developed. For that purpose, there should exist some vertical electrical connections between stacked boards, interposers (e.g., formed from silicon), or dies, so as to pass electrical signals through such stacked structures. Such components have been developed for semiconductor circuits and are currently known as through-silicon vias (TSVs). Example embodiments described herein utilize TSVs with both conducting and superconducting materials while maintaining electrical isolation between them.

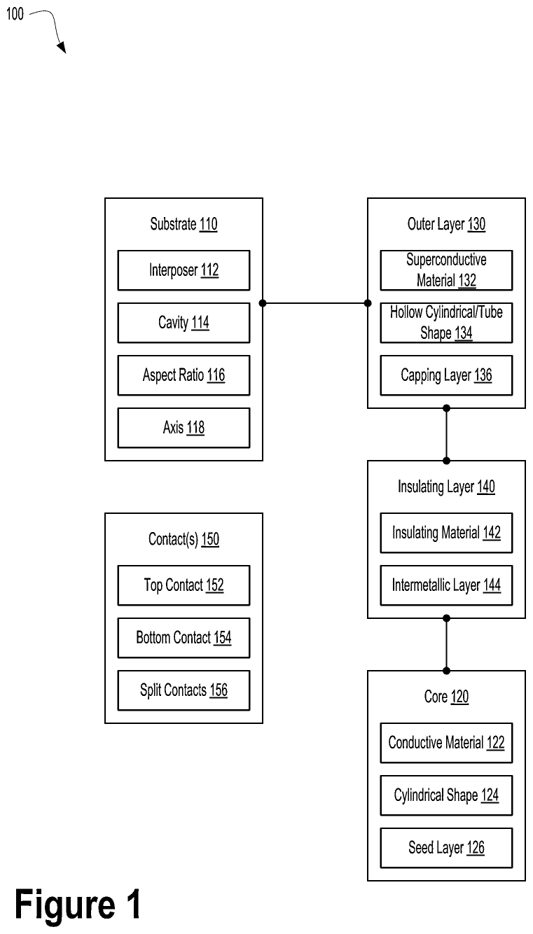

FIG. 1 illustrates a block diagram of a Through-Silicon Via (TSV) 100 in accordance with example embodiments. In some scenarios, the TSV 100 includes a core 120. The core 120 extends through a substrate 110 along an axis 118. In some examples, axis 118 could include a vertical etching axis or could correspond to a crystal plane of the substrate 110.

In various examples, the substrate 110 includes an interposer 112. In some examples, the interposer 112 could include a thin, flat piece of silicon that is used to connect multiple semiconductor dies together. In various examples, the interposer 112 can be made of silicon, but other materials are possible and contemplated.

In such scenarios, the core 120 could include, for example, a cylindrical solid shape 124. For example, the core 120 could resemble a cylindrical plug shape. It will be understood that core 120 could take other shapes so as to fill a portion of a cavity in the substrate 110. Furthermore, in example embodiments, the core 120 includes a conductive material 122. For example, the core 120 could include at least one of: Cu, Ni, Co, or Al. In some embodiments, the room temperature resistivity of the core 120 could be less than 3×10⁻⁸ ohm-m. For instance, the resistivity of copper is approximately 1.68×10⁻⁸ ohm-m at room temperature.

In some embodiments, the core 120 could be configured for operation at cryogenic temperatures (e.g., approximately 4.2 K for liquid helium operation) and has a thermal conductivity of at least 200 W/m.K. For example, the thermal conductivity of copper is approximately 385 W/m.K. Materials with high thermal conductivity may beneficially dissipate heat from electronic components and enable more-efficient cryogenic temperature operation.

The TSV 100 also includes an outer layer 130. In various examples, the outer layer 130 could be disposed about the axis 118 and at least partially surrounding the core 120. In some embodiments, the outer layer 130 could include a hollow cylindrical/tube shape 134 centered about the axis 118, however other shapes and arrangements of the outer layer 130 are possible and contemplated. As described herein, the outer layer 130 includes a superconductive material 132. In various examples, the outer layer 130 may include at least one of: NbTIN, NbN, Nb₃Al, Nb, Ti, Al, Ta, or a combination of such materials. In such scenarios, superconductive material 132 of the outer layer 130 could have a critical temperature of greater than 1 K. It will be understood that other superconductive materials and/or critical temperatures are possible and contemplated. In some embodiments, the outer layer 130 could have a thickness between 10-100 nm.

In various examples, the superconductive material 132 could be selected based on a coefficient of thermal expansion mismatch with silicon. By selecting a superconductive material 132 with a relatively lower CTE mismatch, long term device performance may be beneficially improved due to less material fatigue, cracking, stress, etc.

The TSV 100 additionally includes an insulating layer 140. The insulating layer 140 electrically insulates the core 120 and the outer layer 130 from one another. In some scenarios, the insulating layer 140 could have a thickness of at least 100 nm. However, it will be understood that other thicknesses of the insulating layer 140 are possible and contemplated. For example, the insulating layer 140 could be approximately 30-40 nm thick at the bottom region of the TSV 100. In such scenarios, the insulating layer 140 could be deposited via an atomic layer deposition (ALD) process.

In various embodiments, the insulating layer 140 could include at least one of SiO₂ or SiN. However, other electrically-insulating materials are considered and possible. As an example, the insulating layer 140 could include a SiO₂ film that has been deposited using a tetraethyl orthosilicate (TEOS) as a precursor. In various example embodiments, the insulating layer 140 could be a relatively soft material that can deform under stress without cracking or breaking. The compliance of the insulating layer 140 may beneficially provide stress relief between the outer layer 130 and the core 120. Specifically, the TEOS oxide could help prevent cracks and defects due to CTE mismatch and/or repeated thermal cycling. In some examples, the TEOS oxide may have a Young's modulus of approximately 70 GPa. Other insulating materials with relatively low Young's moduli are possible and contemplated.

In some examples, TSV 100 may include a capping layer 136 along a surface of the outer layer 130. In such scenarios, the capping layer 136 could include SiN or TaN. In various other embodiments, the capping layer 136 could include a material with a relatively short mean free path. With the context of this disclosure, the mean free path is the average distance traveled by a moving particle (such as an electron) between successive collisions with other particles. In some embodiments, the capping layer 136 could beneficially reduce the oxidation of the outer layer 130.

In various other embodiments, TSV 100 may additionally include an intermetallic layer 144 along a surface of the insulating layer 140 and coupled to the core 120. In such scenarios, the intermetallic layer 144 includes TiN. In some examples, the intermetallic layer 144 could include a layer of metal that is compatible with the conductive material 122.

In example embodiments, the TSV 100 may be electrically connected to other circuits and/or devices by way of one or more contacts 150. As an example, the contacts 150 could include a top contact 152 and/or a bottom contact 154. Furthermore, in some embodiments, the contacts 150 could include split contacts 156, which may provide electrically separate connections to the outer layer 130 and the core 120. In various embodiments, the one or more contacts 150 could include a cryo bump metal, such as InSn, Ag, or another material.

In some embodiments, the core 120 could include, or be deposited subsequently to, a seed layer 126. The seed layer 126 could include a thin layer of metal that is deposited on a surface of the semiconductor via prior to copper electroplating to form the conductive material 122 or “plug.” In some instances, the seed layer 126 could provide a surface for the plated material to adhere to, and may beneficially help prevent voids or other defects in the plug. Additionally or alternatively, the seed layer 126 could provide a growth template for the copper crystals, which may beneficially help provide a uniform and isotropic structure for the plug. Yet further, the seed layer 126 could beneficially help to avoid electromigration of metal atoms under an electrical current. In other words, the seed layer 126 could act as a barrier to the movement of copper or other metal atoms. In some instances, the seed layer 126 could be titanium. In such scenarios, the thickness of the seed layer 126 could be between 10 and 100 nm.

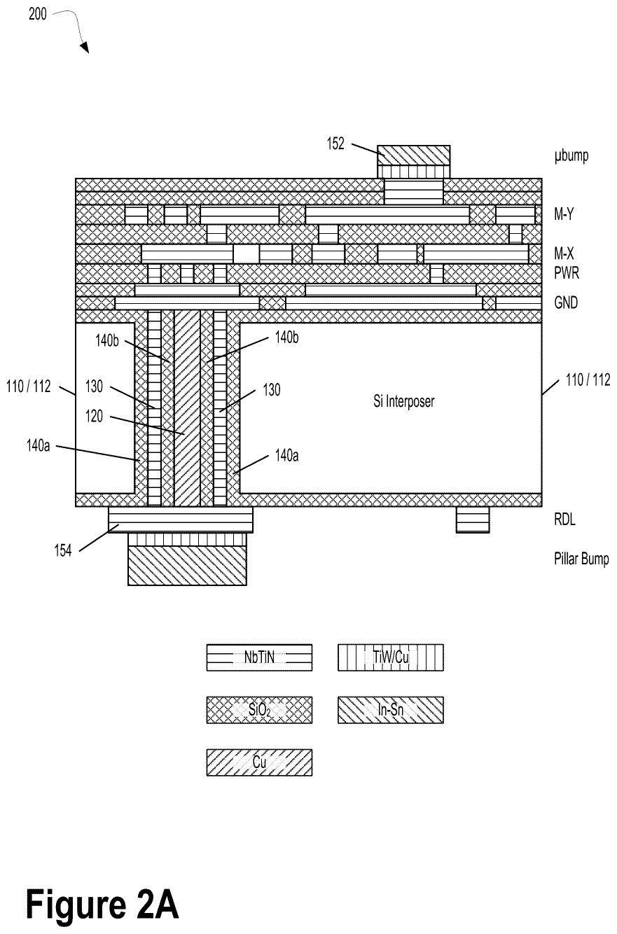

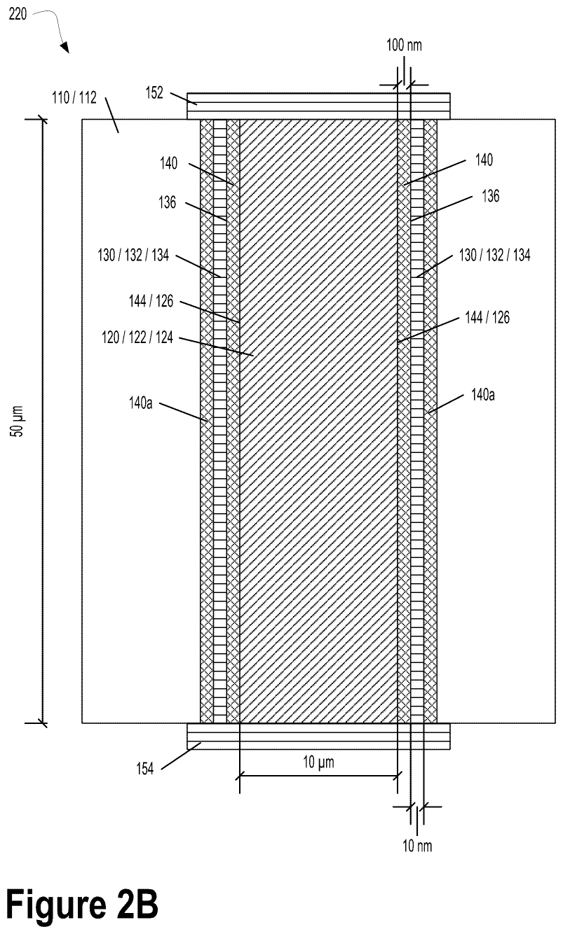

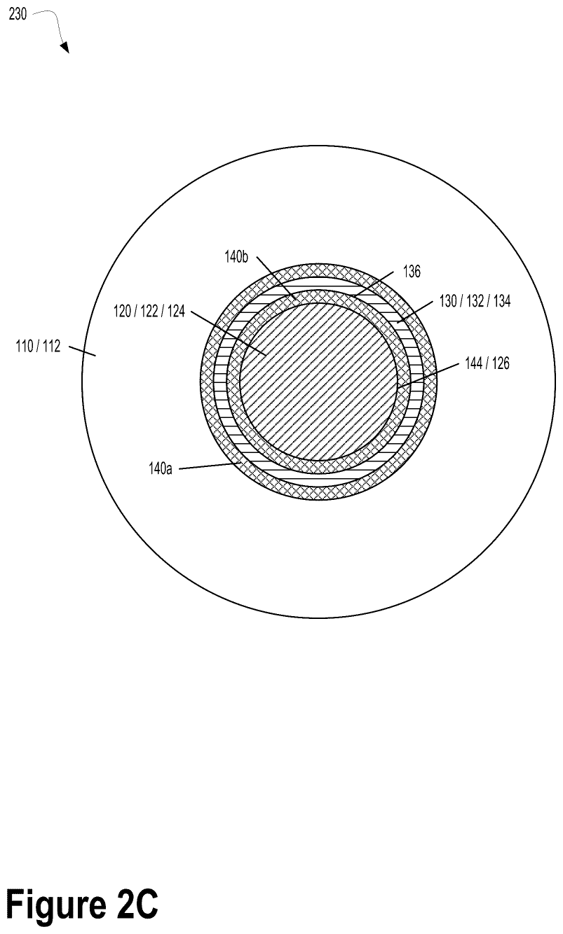

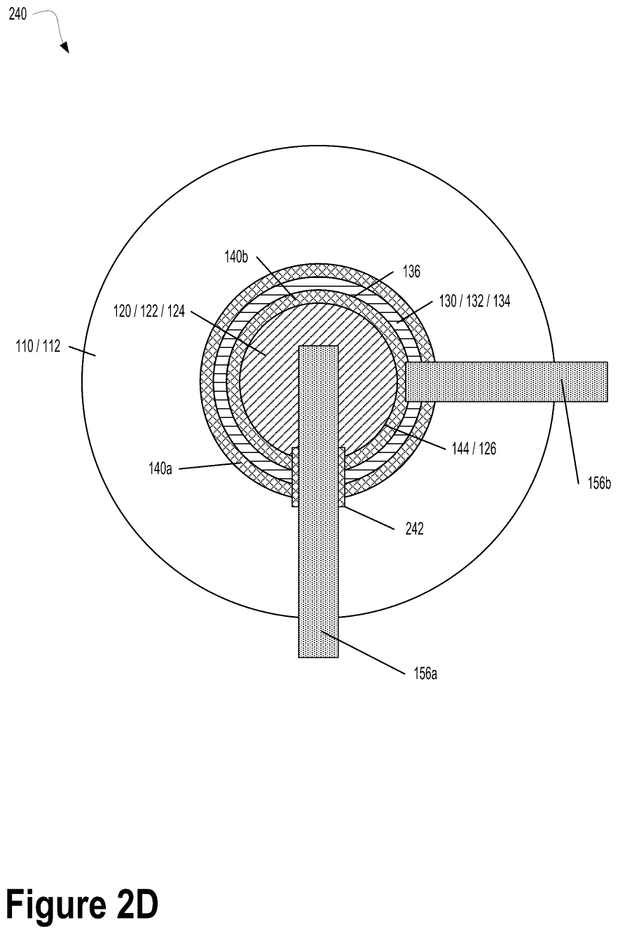

FIG. 2A illustrates a cross-sectional side view 200 of the TSV 100 of FIG. 1 and associated stackup layers in accordance with an example embodiments. As illustrated, FIG. 2A depicts the TSV 100 passing through a silicon interposer and connecting via a connection bump to a device above.

FIG. 2B illustrates a cross-sectional side view 220 of the TSV 100 of FIG. 1 in accordance with an example embodiments. As illustrated, the TSV 100 may appear like a combination of concentric cylinders. However, it will be understood that other shapes are possible and contemplated. Without being limited to the illustration, the thickness of the oxide layers and the superconducting layer could be smaller than the size of the copper core by orders of magnitude. For instance, in some example embodiments, the core 120 could have a diameter of 10 microns. Additionally, the outer layer 130 could have a thickness of about 10 nm. The insulating layer 140b could have a thickness of about 100 nm. It will be understood that other layer thicknesses and ranges of thicknesses are possible and contemplated.

FIG. 2C illustrates a cross-sectional top-down view 230 of the TSV 100 of FIG. 1 in accordance with an example embodiments.

FIG. 2D illustrates a cross-sectional top-down view of a split-channel TSV 240 in accordance with an example embodiments. The split-channel TSV 240 could include a first split contact 156a that may be electrically-connected to the core 120 and corresponding conductive material 122. Note that an insulating bridge 242 may be utilized to isolate the first split contact 156a from the outer layer 130. In such scenarios, split-channel TSV 240 could include a second split contact 156b that is electrically-connected to the outer layer 130 and corresponding superconductive material 132. In such examples, the conductive material 122 and the superconductive material 132 could be addressed separately within the same split-channel TSV 240. It will be understood that split-channel TSV 240 could provide dual-temperature functionality by separating the superconductive and conductive via channels.

### Example Methods

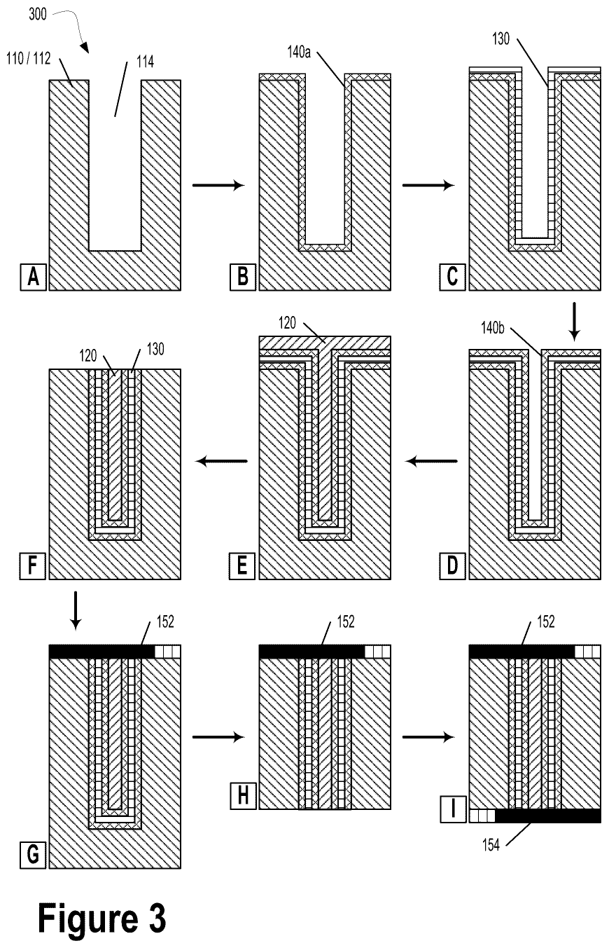

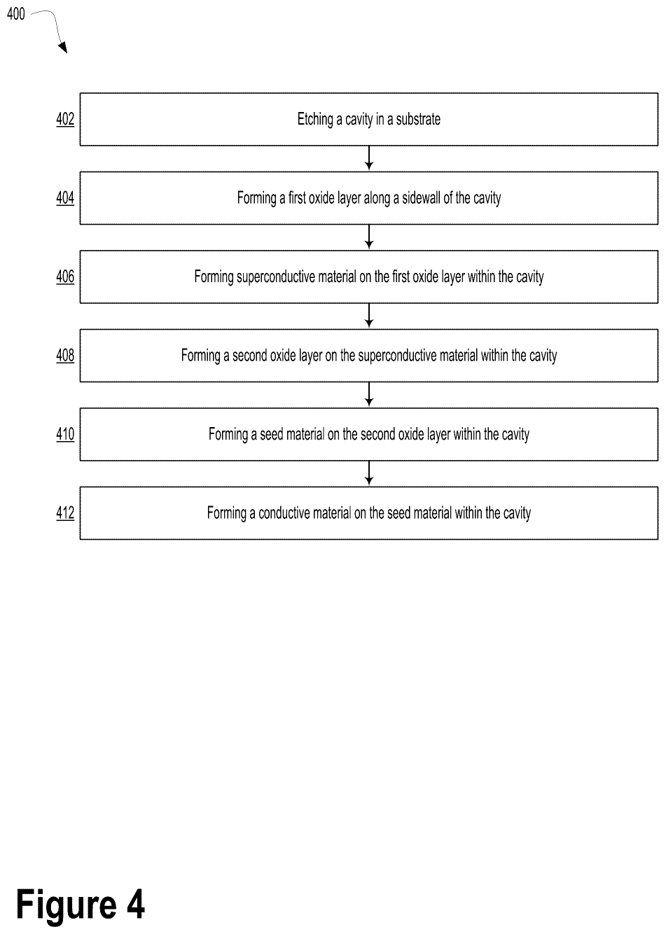

FIG. 3 illustrates various blocks 300 of a method of manufacturing a through-silicon via (TSV) (e.g., TSV 100) in accordance with an example embodiments. FIG. 4 illustrates a method 400 for forming a TSV (e.g., TSV 100) in accordance with an example embodiments. By way of illustrative examples, reference will be made to various blocks 300 of FIG. 3 to describe the steps or blocks of method 400. Although example embodiments may be described as carrying out certain blocks or steps in a particular order, it will be understood that such blocks or steps may be carried out in a different order. Additionally, steps or blocks could be repeated and/or omitted within the scope of this disclosure.

Method 400 includes a method for forming a TSV, which could be similar or identical to TSV 100 as illustrated and described in relation to FIGS. 1, 2A, 2B, and 2C.

Block 402 includes etching a cavity (e.g., cavity 114) in a substrate (e.g., substrate 110), as illustrated in Block A of FIG. 3. Put another way, a hole is patterned in the substrate by applying a mask, some photoresist, and then performing lithography and an etching step. In some scenarios, the cavity could have a depth: width aspect ratio of at least 10:1. Aspect ratios between 5 to 20 are possible and contemplated.

In various examples, etching the cavity may include using a Bosch etch process to achieve substantially vertical sidewalls. The Bosch etching process is a type of deep reactive ion etching (DRIE) that is used to create high aspect ratio (HAR) features in silicon. It is a cyclic process that alternates between two steps: 1) Deposition of a fluorocarbon passivation layer. This layer protects the sidewalls of the etched feature from being etched away. 2) Etching of the silicon at the bottom of the feature. The passivation layer is not etched by the plasma, so it protects the sidewalls while the silicon at the bottom of the cavity is etched away. This process is repeated many times to create a deep, narrow feature with vertical sidewalls. It will be understood that other types of anisotropic etch processes are also contemplated and possible within the scope of this disclosure.

In various embodiments, the substrate could include an interposer (e.g., interposer 112). In such scenarios, the interposer may include silicon. It will be understood that other types of substrates are possible and contemplated.

Block 404 includes forming a first insulating layer (e.g., insulating layer 140a) along a sidewall of the cavity, as illustrated in Block B of FIG. 3. In other words, an insulating oxide liner layer could be deposited (e.g. with chemical vapor deposition) along the exposed surface of the substrate, including within the cavity.

Block 406 includes forming an outer layer (e.g., outer layer 130) on the first insulating layer within the cavity, as illustrated in Block C of FIG. 3. As described elsewhere herein, the outer layer includes a superconductive material. The layer of superconducting material may be deposited (e.g. with sputtering) on top of the underlying oxide layer. Some non-limiting examples of superconducting material could be nitride (N) or non-nitride material, both comprising niobium (Nb), titanium (Ti), aluminum (Al), tantalum (Ta), or a combination of them.

In some examples, forming the outer layer could include physical vapor deposition, atomic layer deposition, or other methods for conformal material deposition. In various embodiments, the outer layer could have a thickness of between 10-100 nanometers. It will be understood that the outer layer thickness may not be perfectly conformal within the via. Accordingly, in some scenarios, the outer layer could be 1-10 nm thick at a bottom of the cavity and about 100 nm thick along the sidewalls of the cavity. Accordingly, forming the outer layer using a deposition technique may be performed until a desired sidewall layer thickness or desired bottom layer thickness is achieved.

Method 400 may also include forming a capping layer (e.g., capping layer 136) on the superconducting material. In some examples, the capping layer may help prevent oxidation of the superconducting material. In such scenarios, the capping layer could include SiN, TaN, or another material with a short mean free path. Other capping layer materials are possible and contemplated.

Block 408 includes forming a second insulating layer (e.g., insulating layer 140_{b}) on the outer layer within the cavity, as illustrated in Block D of FIG. 3. In some embodiments, forming the first insulating layer or forming the second insulating layer comprises a tetraethyl orthosilicate (TEOS)/O₃ process or a plasma enhanced atomic layer deposition (PEALD) process. In some embodiments, the second insulating layer could have a similar or identical thickness to that of the first insulating layer (e.g., 100 nm thickness). Alternatively, the insulating layers could have different thicknesses.

TEOS oxide is a type of silicon dioxide that is formed by the chemical vapor deposition (CVD) of tetraethyl orthosilicate (TEOS). TEOS is a colorless liquid that is hydrolyzed into silicon dioxide and ethanol when it comes into contact with water. In the CVD process, TEOS is vaporized and then introduced into a reaction chamber where it is exposed to a high temperature and a reactive gas, such as oxygen. The TEOS molecules are then decomposed and the silicon atoms react with the oxygen atoms to form silicon dioxide.

Plasma-enhanced atomic layer deposition (PEALD) is a variation of atomic layer deposition (ALD) that uses a plasma to enhance the reactivity of the precursor molecules. This process allows for the deposition of films at lower temperatures and with higher growth rates than traditional ALD.

Block 410 includes forming a seed layer (e.g., seed layer 126) on the second insulating layer within the cavity. In such scenarios, forming the seed layer could include forming a diffusion barrier layer. The diffusion barrier layer may beneficially prevent any diffusion of the conducting material (e.g. copper) into the liner (e.g., the second insulating layer). In various examples, a barrier layer (e.g. Tantalum (Ta) deposited by physical vapor deposition (PVD), TiN deposited by ALD, or tungsten nitride (WN) deposited by ALD may be initially formed. Other types of diffusion barrier layers are possible and contemplated. Subsequently, a seed layer is deposited in such a way that it will allow the later filling of the TSV with copper through electroplating. In various embodiments, the seed layer could be approximately 800 nm-1.5 microns in thickness. Additionally or alternatively, the seed layer could include 130 nm of Ta. In some scenarios, the process of blocks 410 and 412 may be conducting under vacuum conditions and may be performed serially without breaking vacuum.

Block 412 includes forming a core on the seed layer within the cavity, as illustrated in Block E of FIG. 3. Forming the core could include an electroplating process that is performed from the bottom up and leads to a possible overburden of conducting material at the top of the TSV. As described herein, the core includes a conductive material (e.g., conductive material 122). In such scenarios, the electroplating process may include using a high-purity copper electroplating solution to fill the remaining open volume in the cavity. In some embodiments, method 400 could include a post-plating annealing process, which may include heating the TSV to approximately 420° C. in N₂ ambient.

In various example embodiments, method 400 could include several other steps or blocks in the process to fabricate TSVs. For example, method 400 may include, subsequent to forming the core, planarizing a first surface of the substrate, with a chemical-mechanical-polishing (CMP) process, as illustrated in Block F of FIG. 3. In some examples, after the electroplating process, the conductive material could come into contact with the superconducting material due to the overburden. In order to electrically isolate the two conductors from each other, a polishing is performed with some abrasive slurry to remove the non-desired layers. In such scenarios, the CMP process may beneficially remove overlapping conductive/superconductive layers to avoid electrical shorts.

In such scenarios, the CMP process could be used to remove material from the first surface using a combination of chemical and mechanical forces. For example, the substrate could be placed on a rotating polishing pad. The pad may be covered with a slurry that contains abrasive particles and chemical reagents. The slurry is circulated over the substrate as the pad rotates. The abrasive particles in the slurry physically remove material from the wafer surface, while the chemical reagents in the slurry chemically etch the surface. In some examples, multiple slurry mixtures may be used in succession to obtain a desired smoothness and/or flatness of the substrate surface. In such scenarios, the combination of mechanical and chemical action results in a highly smooth and planar surface.

Method 400 may also include patterning a first surface of the substrate and forming a plurality of superconducting wires on the first surface of the substrate based on the patterning, as illustrated in Block G of FIG. 3. In such scenarios, the front side of the substrate could be patterned with structures such as superconducting wires created with a semi-damascene process. The possible processes that can be performed may include hard masking, deposition of conducting or superconducting material, application of photoresist, lithography, etching, passivation, and/or oxide interlayer dielectric linear deposition. In various example embodiments, the formed plurality of superconducting wires could provide various superconducting devices and/or circuits, such as Josephson junctions or superconducting qubits.

In some example embodiments, the formation of the plurality of superconducting wires may include conformal deposition of superconductive material, followed by a patterned etch, dielectric deposition, and patterned dielectric etch. It will be understood that other ways to form the plurality of superconducting wires are contemplated and possible.

Method 400 may additionally include thinning a second surface (e.g., a backside surface) of the substrate to a desired substrate thickness, as illustrated in Block H of FIG. 3. As described elsewhere, the thinning process could include a CMP process. Additionally or alternatively, the thinning process could include mechanical grinding, wet etching or dry etching. In some examples, method 400 may include an initial dry etch to cause the outer layer to protrude from the substrate surface. Subsequently, a CMP knockoff process could be performed to remove remaining protruding portions of the outer layer.

Method 400 may further include patterning the second surface of the substrate and forming a plurality of superconducting wires on the second surface of the substrate based on the patterning, as illustrated in Block I of FIG. 3. In some embodiments, the formation of the plurality of superconducting wires on the second surface could include a relatively low temperature deposition of NbTiN (e.g., less than 200° C.). Specifically, the process details could be selected to avoid delamination of a hybridized substrate attached using glue or other adhesive materials.

### Example Bump Structures and Formation Methods

Within the scope of the present disclosure, it will be understood that the TSV 100 could be electrically connected to circuits and/or superconducting devices on other substrates via electrically conductive structures, such as bump bonds. Bump bonds create electrical connections between a semiconductor die and a substrate. The bumps are typically made of various conductive metals, such as gold or copper, and they are deposited on the die and the substrate using a variety of methods, such as evaporation, plating, or screen printing. Various conductive materials, such as In, InSn, and/or Ag are also possible and contemplated for use with the bump bonds.

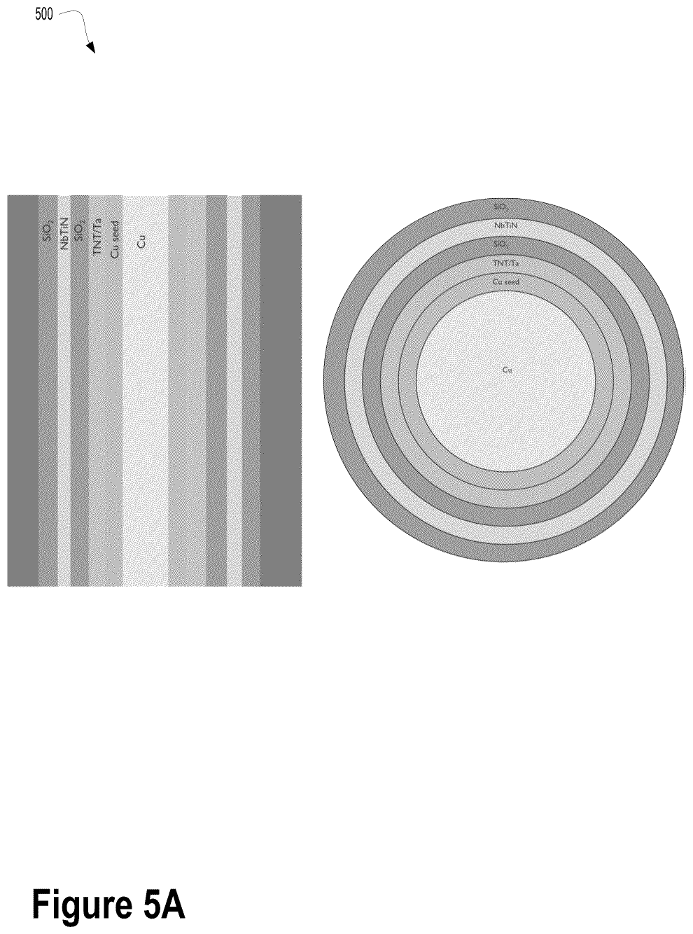

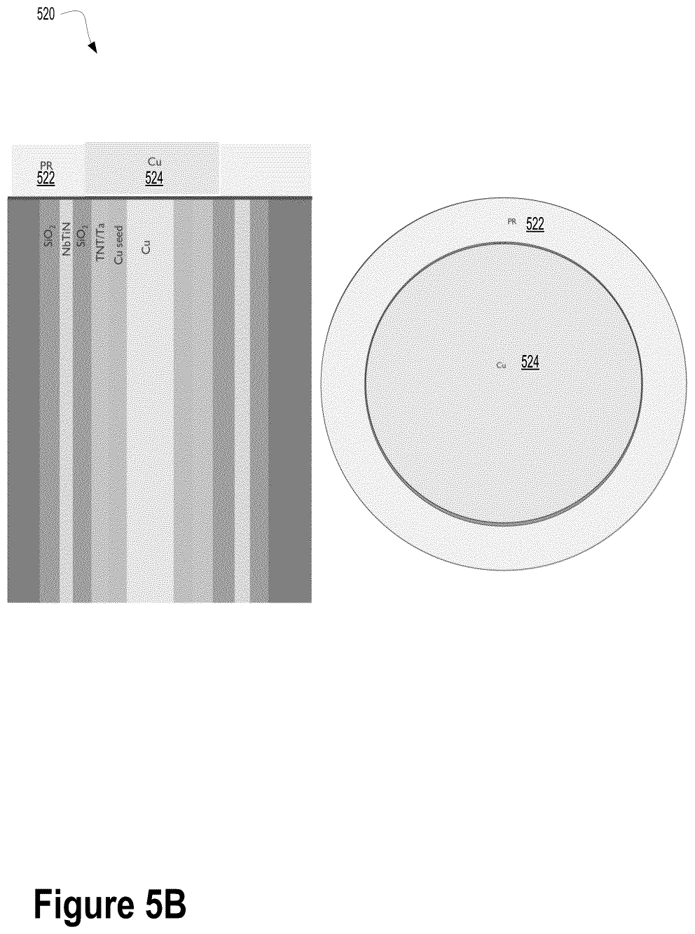

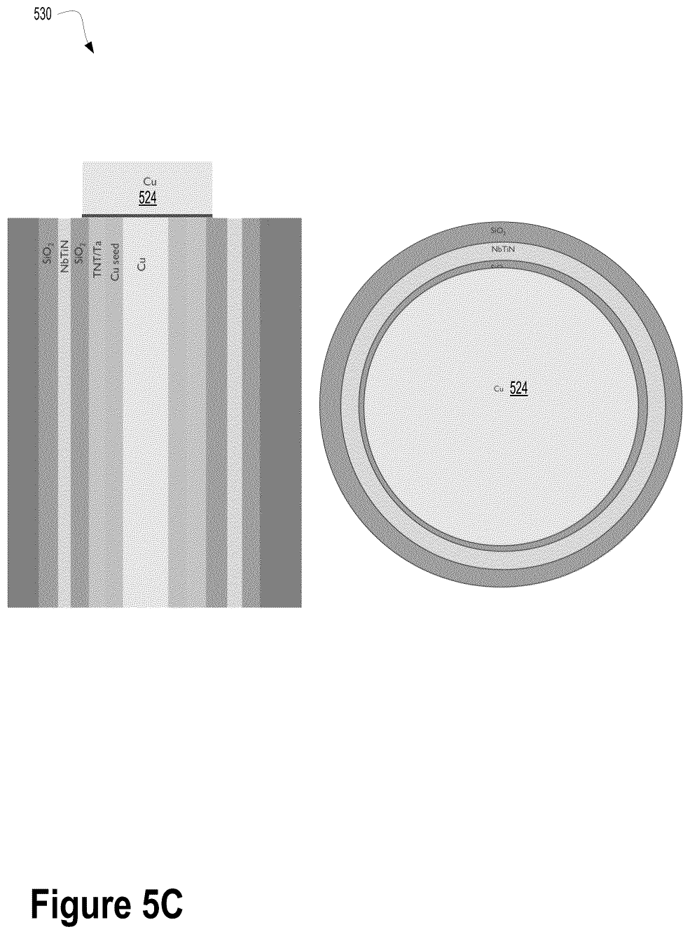

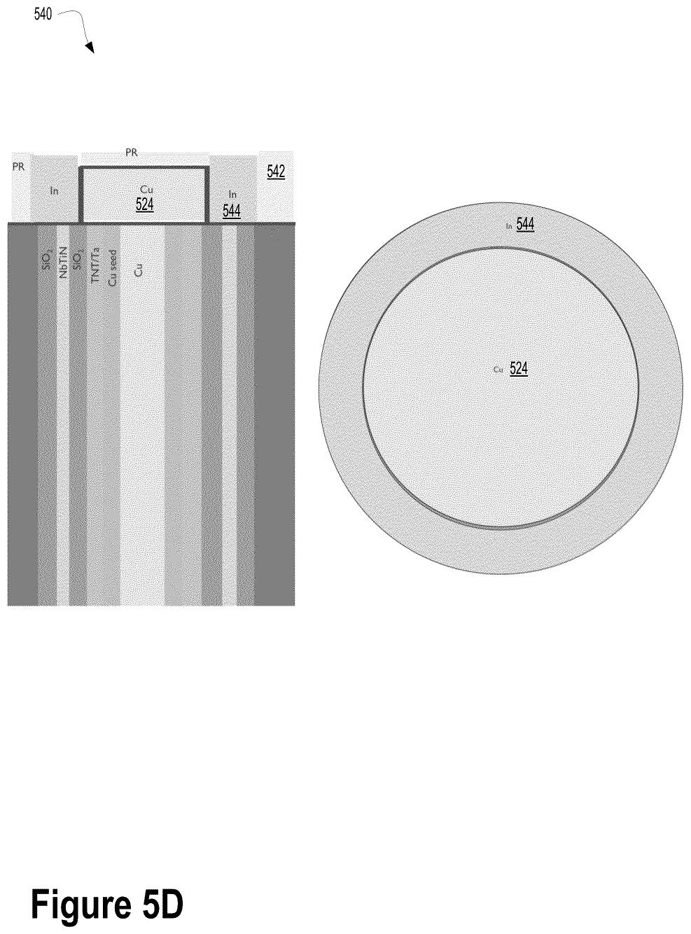

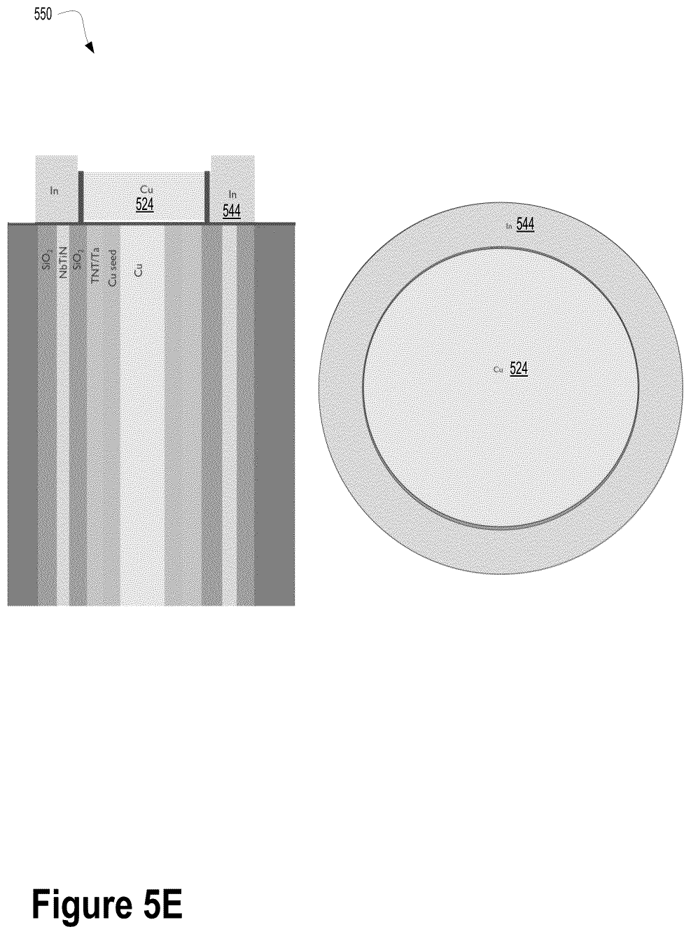

FIGS. 5A, 5B, 5C, 5D, and 5E illustrate various blocks or steps in a manufacturing process that may form bump bonds. FIG. 5A-5E could include similar or identical elements as those illustrated and described in relation to FIG. 1.

FIG. 5A illustrates a cross-sectional side and top-down views 500 of a TSV (e.g., TSV 100). Views 500 may illustrate a dual-side planarized version of TSV 100 in which the via is exposed on both top and bottom sides of substrate 110.

FIG. 5B illustrates a cross-sectional side and top-down views 520 of the TSV with a copper bump 524 that has been photolithographically defined with a first photoresist mask 522.

FIG. 5C illustrates a cross-sectional side and top-down views 530 of the TSV with copper bump 524 and first photoresist mask removed.

FIG. 5D illustrates a cross-sectional side and top-down views 540 of the TSV with indium bump 544 that has been photolithographically defined with a second photoresist mask 542. As illustrated in views 540, the indium bump 544 may be proximate to the superconducting NbTiN vias (e.g., superconducting material 132), while the copper bump 524 may be proximate to the copper core (e.g., core 120).

FIG. 5E illustrates a cross-sectional side and top-down views 550 of the TSV with indium bump 544, copper bump 524, and second photoresist mask removed. In some example embodiments, a similar process could be carried out on the backside of the substrate to form indium bumps and copper bumps on the other surface of the substrate.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

Claims what is claimed is:

1. A through-silicon via (TSV) comprising:
a core, wherein the core extends through a substrate along an axis, wherein the core comprises a conductive material;
an outer layer, wherein the outer layer is disposed about the axis and at least partially surrounding the core, wherein the outer layer comprises a superconductive material; and
an insulating layer, wherein the insulating layer electrically insulates the core and the outer layer from one another.

2. The TSV of claim 1, wherein the core comprises at least one of: Cu, Ni, Co, or Al.

3. The TSV of claim 1, wherein the core is configured for operation at cryogenic temperatures and has a thermal conductivity of at least 200 W/m.

4. The TSV of claim 1, wherein the outer layer comprises at least one of: NbTiN, NbN, Nb₃Al, Nb, Ti, Al, Ta, or a combination of such materials.

5. The TSV of claim 1, wherein the outer layer has a critical temperature of greater than 5 K.

6. The TSV of claim 1, wherein the outer layer comprises a thickness between 10-100 nm.

7. The TSV of claim 1, wherein the insulating layer comprises a thickness of between 30 nm and 50 nm.

8. The TSV of claim 1, wherein the insulating layer comprises at least one of: SiO₂ or SiN.

9. The TSV of claim 1, wherein the insulating layer comprises a SiO₂ film deposited using a tetraethyl orthosilicate (TEOS) as a precursor.

10. The TSV of claim 1, wherein the substrate comprises an interposer, wherein the interposer comprises silicon.

11. The TSV of claim 1, further comprising a capping layer forming a surface of the outer layer, wherein the capping layer comprises SiN or TaN.

12. The TSV of claim 1, further comprising a top contact, wherein the top contact comprises:
an indium bump that is electrically coupled to the outer layer; and
a copper bump that is electrically coupled to the core.

13. A method for forming a through-silicon via (TSV), the method comprising:
etching a cavity in a substrate;
forming a first insulating layer along a sidewall of the cavity;
forming an outer layer on the first insulating layer within the cavity, wherein the outer layer comprises a superconductive material;
forming a second insulating layer on the outer layer within the cavity;
forming a seed layer on the second insulating layer within the cavity; and
forming a core on the seed layer within the cavity, wherein the core comprises a conductive material.

14. The method of claim 13, further comprising:
subsequent to forming the core, planarizing a first surface of the substrate, with a chemical-mechanical-polishing (CMP) process;
patterning a first surface of the substrate;
forming a plurality of superconducting wires on the first surface of the substrate based on the patterning;
thinning a second surface of the substrate to a desired substrate thickness;
patterning the second surface of the substrate; and
forming a plurality of superconducting wires on the second surface of the substrate based on the patterning.

15. The method of claim 13, wherein the cavity has a depth: width aspect ratio of at least 10:1.

16. The method of claim 13, wherein etching the cavity comprises using a Bosch etch process to achieve substantially vertical sidewalls.

17. The method of claim 13, wherein forming the first insulating layer or forming the second insulating layer comprises a tetraethyl orthosilicate (TEOS)/O₃ process or a plasma enhanced atomic layer deposition (PEALD) process.

18. The method of claim 13, further comprising forming a capping layer on the superconducting material, wherein the capping layer comprises SiN or TaN.

19. The method of claim 13, wherein forming the seed layer comprises forming a diffusion barrier layer, wherein the diffusion barrier layer comprises at least one of: Ta deposited by physical vapor deposition (PVD), TiN deposited by atomic layer deposition (ALD), or WN deposited by ALD.

20. The method of claim 13, further comprising:
forming an indium bump along a first surface of the substrate, such that the indium bump is electrically coupled to the outer layer; and
forming a copper bump along the first surface of the substrate, such that the copper bump is electrically coupled to the core.
